(19) United States
(12) Patent Application Publication
(10) Pub. No.: US 2017/0018069 A1
(43) Pub. Date: Jan. 19, 2017

(54) HYBRID METROLOGY TECHNIQUE

(71) Applicants: Globalfoundries Inc., Grand Cayman (KY); Nova Measuring Instruments Ltd., Rehovot (IL)

(72) Inventors: Alok Vaid, Ballston Lake, NY (US); Cornel Bozdong, San Jose, CA (US); Shay Wolfling, Qiryat-Ono (IL); Matthew J. Sendelbach, Fishkill, NY (US); Jamie Tsai, Clifton Park, NY (US); Cermen Osorio, Ballston Spa, NY (US)

(21) Appl. No.: 15/120,692

(22) PCT Filed: Oct. 30, 2014
(86) PCT No.: PCT/IL2014/050940

§ 371 Date: Aug. 22, 2016

Related U.S. Application Data
(60) Provisional application No. 61/943,392, filed on Feb. 23, 2014.

(51) Int. Cl. G06T 7/00; G01B 15/02; H01J 37/28; G01B 11/06

(52) U.S. Cl. CPC G06T 7/0004; G01B 11/06; G01B 15/02; H01J 37/28; G06T 2207/30148; G06T 2207/10116; G06T 2207/10061

(57) ABSTRACT

A computerized system and method are provided for use in measuring at least one parameter of interest of a structure. The system comprises a server utility configured for data communication with at least first and second data provider utilities. The server utility receives, from the server provider utilities, measured data comprising first and second measured data pieces of different types indicative of parameters of the same structure; and is capable of processing the first and second measured data pieces for optimizing one or more first parameters values of the structure in one of the first and second measured data pieces by utilizing one or more second parameters values of the structure of the other of said first and second measured data pieces.

### TECHNOLOGICAL FIELD AND BACKGROUND

The present invention is in the field of metrology techniques, in particular useful for measuring on patterned structures, such as semiconductor wafers. The invention relates to an optical measurement system and method implementing a hybrid metrology technique.

Advanced device architecture and shrinking dimensions of pattern features in patterned structures pose an increasing challenge on dimensional metrology toolsets. More profile details about the pattern, such as metal undercut, side wall angle (SWA), footing, rounding, proximity, etc., need to be extracted with greater measurement certainty to support the current and future needs of process control. The metrology toolsets commonly used in the semiconductor industry FAB s are practically incapable of measuring all needed parameters of the structure with the required accuracy and precision. Hybrid Metrology (HM) technique is aimed at improving the accuracy, precision or other metrology performance of measurements by combining information from different toolsets to provide increased metrology performance for complex multi-stack structures of various types, including FinFET devices (i.e. Field Effect transistor in which the conducting channel is wrapped by a thin silicon “fin”, which forms the body of the device).

According to the known HM approach, the information measured by a secondary toolset (typically, critical dimensions Scanning Electron Microscopy (CD-SEM)) is used as input constraint on the modeling analysis of a primary toolset (typically, optical critical dimension (OCD)). For example, WO 2011/158239, assigned to Nova Measuring Instruments Ltd., describes a system and method for use in inspection and metrology of patterned structures, including data input utility for receiving first type of data indicative of image data on at least a part of the patterned structure, and data processing and analyzing utility configured and operable for analyzing the image data, and determining a geometrical model for at least one feature of a pattern in the structure, and using this geometrical model for determining an optical model for second type of data indicative of optical measurements on a patterned structure. In this technique, optimization of the interpretation models of two tools (OCD and CD-SEM tools) is performed using measured data from both tools, by creating a combined model.

### GENERAL DESCRIPTION

There is need in the art for a novel Hybrid Metrology based technique, which improves and also extends the usability of Hybrid Metrology, for, among other things, improved performance and cost-effectiveness.

As indicated above, to date, the information measured by the secondary toolset (CD-SEM) is used as input constraint on the modeling analysis of the primary toolset (OCD). In other words, the known metrology technique utilizes standard hybridization, a so-called “sequential hybridization”, of data from one toolset to another. While this sequential hybridization is generally successful, there are cases where it does not sufficiently or at all improve the measurement results. The reason for this is associated with the fact that a “threshold” parameter used to analyze CD-SEM images does not provide a reading of the CD value at a well defined height of the structure being measured, but the CD value provided corresponds to ill-defined heights, correlated with other parameters of the structure such, as sidewall angle (SWA).

The technique of the present invention enables to remove this correlation for better matching of data (between at least two tools, and to a reference system) and thus provide better Hybrid Metrology results. The present invention utilizes the concept of a so-called “co-optimization” based hybridization, where, for example, image analysis parameters of a secondary tool (e.g. CD-SEM, X-ray tool) are modulated by profile information from a primary tool, OCD (scatterometry), while the OCD extracted profile is concurrently optimized (to minimize errors) through addition of the results (CD) of e.g. CD-SEM.

More specifically, the present invention can be used for OCD and CDSEM measurements, and is therefore exemplified below with respect to this specific application. It should, however, be noted that the invention is not limited to this specific example, and CDSEM measurements may be replaced by or used in addition with other secondary tools, such as X-ray measurements. It should thus be understood that the principles of the present invention can be used for any suitable combination of primary and secondary tools, in order to resolve uncertainties of measurements associated with that measurement of one parameter is not be impacted by or correlated to the variation of another parameter.

The co-optimization method of the present invention is a step forward to extending the applicability of hybrid metrology by identifying synergies between the two methods and removing matching artifacts. Current methods of “standard” hybrid metrology could not account for the differences in physics of the measurement. Therefore the standard approach of Hybrid Metrology is sometimes limited in solving the measurement issue.

The technique of the present invention is actually the next level of advancement in Hybrid Metrology, i.e. co-optimization or concurrent/simultaneous hybridization, such as concurrent optimization of CD-SEM and OCD raw data—SEM image and OCD spectrum. The technique of the present invention is based on the general approach (improvement of OCD using CDSEM, improvement of CD-SEM using OCD), but utilizes a novel technique for combining these different type measurements which results in a new methodology and flow with performance that could not be achieved with the conventional techniques of the kind specified.

Generally, the invention may utilize a model-based secondary measurement (e.g. CD-SEM) technique combined with model-based OCD approach. However, image-analysis based CD-SEM is much more prevalent in industry than model based CD-SEM. Therefore, in the description below, the co-optimization is demonstrated using CD-SEM image analysis empirical parameters (commonly referred as CD-SEM measurement algorithms parameters) combined with OCD model parameters.

It should be noted for the CD-SEM and OCD measurements, the initial, individual results of the combination of two techniques were found incompatible as the two techniques are measuring different aspects of the structure. The inventors have shown that the co-optimization hybridization technique of the invention provides for successively using these two measurement techniques together, which standard (sequential) hybridization not always is enabling.

The inventors have understood that the secondary tool (e.g. CD-SEM) threshold modulation can be used as a function to solve the above problem. Indeed, the same percentage threshold of the histogram can reflect CD values at different height of the structure. While the values might be “correct” by themselves, they have to be specified in relation to the actual structure to be measured. After all, there is always a range of “true” CDs along any fin structure, and any value of CD in that range will naturally correspond to a real CD. The height along the fin profile that corresponds to the CD measured renders the co-optimized hybridization successful. CD-SEM response is sensitive to the profile detail. However, since it is capable of measuring a single independent parameter, a flat threshold, as used today, reflects CD values at different physical heights of the feature. This is especially true for the small CDs of the advanced features like FinFETs, where the “gray scale” edges of the lines represent an increasing percentage of the CD measured (“blur” is constant, CD decreases). Hence, CD-SEM may be used as “reference” for OCD. Many applications where “standard” hybrid was applied can further benefit from the refinements of co-optimization.

Thus, according to one broad aspect of the invention, there is provided a computerized system for use in measuring at least one parameter of interest of a structure, the system comprising:

a server utility configured for data communication with at least first and second data provider utilities, for receiving therefrom measured data comprising first and second measured data pieces of different types indicative of parameters of the same structure, said server utility being configured and operable for concurrently processing said first and second measured data pieces for optimizing one or more first parameters values of the structure in one of the first and second measured data pieces by utilizing one or more second parameters values of the structure of the other of said first and second measured data pieces.

In some embodiments, the server utility comprises: a first processing utility connected to the first data provider for receiving the first measured data piece and determining said one or more first parameters values; a second processing utility connected to the second data provider for receiving the second measured data piece and determining said one or more second parameters values; and a hybrid co-optimization utility connected to the first and second processing utilities, for receiving and processing said one or more first parameters values and said one or more second parameters values, and generating optimized model data for use by at least one of the first and second processing utilities for processing the respective measured data pieces.

In some embodiments, the server utility is further connectable to an additional data provider associated with a reference measurement system for providing reference data about at least one parameter of the same or similar structure.

The first and second parameters may include the at least one parameter of interest, or alternatively the server utility may be configured and operable for using at least one of the first and second parameters for determining the at least one parameter of interest. The at least one parameter of interest of the structure may include a parameter of a pattern in the structure, and/or a thickness of a layer in the structure.

In some embodiments, the second measured data (constituting primary tool measured data) includes OCD measured data. The first measured data (constituting secondary tool measured data) may include either one or both of CD-SEM and X-ray measured data.

The present invention can be used for measuring in patterned structures, such as Field Effect Transistors, e.g. FinFET.

In some embodiments, the server utility is configured and operable for utilizing a threshold modulation of the CD-SEM measured data for determining critical dimension (CD) values along a profile of a pattern in the structure, as reference for analyzing the OCD measured data.

According to another broad aspect of the invention, there is provided a measurement system for use in measuring at least one parameter of interest of a structure, the measurement system comprising: at least first and second data provider utilities for providing measured data comprising first and second measured data pieces of different types indicative of parameters of the same structure; and the above-described server utility in communication with said at least first and second data provider utilities, and preferably also with an additional data provider associated with a reference measurement system for providing reference data about at least one parameter of the same or similar structure.

According to yet another broad aspect of the invention, there is provided a measurement tool for measuring at least one parameter of interest of a structure, where the measurement tool comprises: a measured data provider for providing data indicative of one or more measured parameters of a structure; and the above-described server utility in communication with the measured data provider.

According to yet another broad aspect of the invention, there is provided a method for use in measuring at least one parameter of interest of a structure. The method comprises: receiving first measured data of a first type indicative of the structure, and processing said first measured data, and determining one or more first parameters values of the structure; receiving second measured data of a second type indicative of the same structure, and processing said second measured data, and determining one or more second parameters values of the structure; analyzing said first and second parameters values of the structure, and generating optimized model data for use in processing at least one of the first and second measured data.

As indicated above, the structure may be a patterned structure, and the parameter(s) of interest may include at least one parameter of a pattern in the structure and/or a thickness of a later in the structure.

In some embodiments of the invention, it is used for measuring in FinFET structures, utilizing OCD measured data (primary tool) and CD-SEM measured data (secondary tool). The analysis of the first and second parameters values of the structure comprises utilizing image based threshold modification of CD-SEM measured data for optimizing modeling of the OCD measurements.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1A schematically illustrates the main principles of the standard Hybrid Metrology;

FIG. 1B schematically illustrates the main principles of the co-optimization Hybrid Metrology of the invention;

FIGS. 2A to 2C exemplify construction and operation of a system of the invention, where FIG. 2A exemplifies a setup phase of measurements, FIG. 2B exemplifies a production phase of measurements, and FIG. 2C shows a flow diagram of data processing;

FIG. 2D shows a flow diagram of the example of the inventors for using the OCD data to improve the CD-SEM data by noise removal therefrom;

FIGS. 3A and 3B illustrate a fin structure used in the simulation of the measurement technique of the invention, where FIG. 3A illustrates a typical top-down CD-SEM fragment of image, FIG. 3B illustrates a typical X-SEM lateral image, and FIG. 3C illustrates the OCD model of the fin indicating some of the parameters of interest;

FIGS. 4A-4D show schematics of the CD-SEM image analysis, where FIG. 4A shows the sample TEM image with HN and IL features and corresponding OCD model curves, FIG. 4B shows secondary electron signal intensity, FIG. 4C shows the differential curve, and FIG. 4D shows the sample SEM image;

FIG. 5 shows the CD-SEM measurement of CD using different settings for selected algorithm parameters for the set of wafers under measurements;

FIG. 6 illustrates CD extracted with the CD-SEM using different settings for another algorithm parameter;

FIG. 7 shows OCD measurements of CD along the fin;

FIG. 8 shows “standard” OCD results for the parameters of interest, and comparison to reference (where available);

FIG. 9 illustrates the results of threshold of CD-SEM algorithm parameter modulation using OCD profile details, which in turn are refined using corrected CD data from CD-SEM;

FIG. 10 shows the results of hybrid co-optimization technique of the invention applied to the measurements on IL DOE wafers.

### DETAILED DESCRIPTION OF EMBODIMENTS

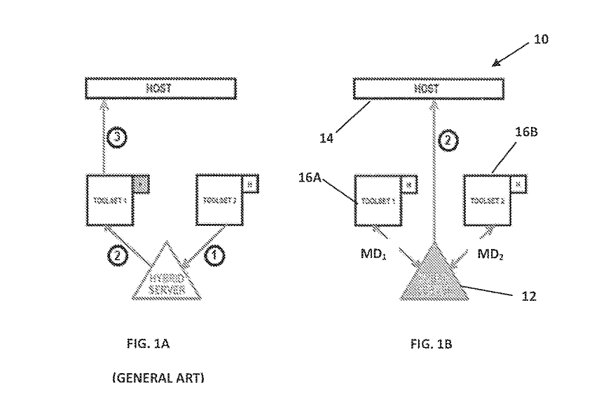

Reference is made to FIGS. 1A and 1B exemplifying the main principles of the Hybrid Metrology technique of the present invention (FIG. 1B), as compared to those of the standard Hybrid Metrology (FIG. 1A). The standard Hybrid Metrology utilizes a sequential optimization approach (one tool at a time). As exemplified in FIG. 1A, toolset 1 utilizes data from toolset 2, and hybridization takes place at toolset 1.

The Hybrid Metrology technique of the present invention is based on simultaneous optimization of multiple tools. As shown in FIG. 1B, measured data from toolsets 1 and 2 is optimized simultaneously, and hybridization takes place at a hybrid server.

Thus, FIG. 1B actually illustrates, by way of a block diagram, an example of a measurement system 10 of the present invention. The system 10 is configured as a computerized system including inter alia data input and output utilities and memory utility which are not specifically shown, and a server utility 12 (termed here “hybrid server”) which is associated with a FAB's host system 14 (i.e. is connectable to the FAB's host system 14 via wires or wireless signal transmission, or is a structural module of such the FAB's host system 14), and is also connected (via wires or wireless signal transmission) to measured data provider utilities 16A and 16B. These may be utilities of the same or different data storage units (off-line measurement mode), or may be measurement units (on-line mode), or one may be the storage device and the other be the measurement unit.

The hybrid server utility 12 is connected to both (generally, to multiple) measured data provider utilities 16A and 15B providing measured data of different types about the same structure, and is configured and operable for concurrent data exchange MD₁ and MD₂ with respect to different measurements on the same structure and optimizing both types of measurements or optimize interpretation of both types of measured data. This will be described more specifically further below.

Hybrid Metrology in general is a complex process of adapting data from one toolset and making it usable to improve the performance of another toolset. In the earlier work of the inventors, data modification parameters are identified as any parameter that modulates the hybridization of data or modifies how data are used during hybridization (for example “strength of hybridization”, “measurement offset” or “technology matching” parameters). In the sequential or standard Hybrid Metrology data available from a secondary tool (Toolset 2 in FIG. 1A) is utilized by primary tool (Toolset 1 in FIG. 1A). In the technique of the invention (FIG. 1B), termed “co-optimization”, the raw data from both secondary and primary toolsets are simultaneously optimized in a complementary methodology.

The inventors have found that “standard” Hybrid Metrology falls short of improving on the individual toolsets results, and that a deeper understanding of fundamental differences between the two toolsets is needed. The principles of the present invention are exemplified here for a more practical case of using image-analysis based CD-SEM (and not model based), and the co-optimization is therefore demonstrated using CD-SEM measurement algorithms parameters combined with OCD model parameters. It should, however, be understood that the principles of the present invention are not limited to this specific application.

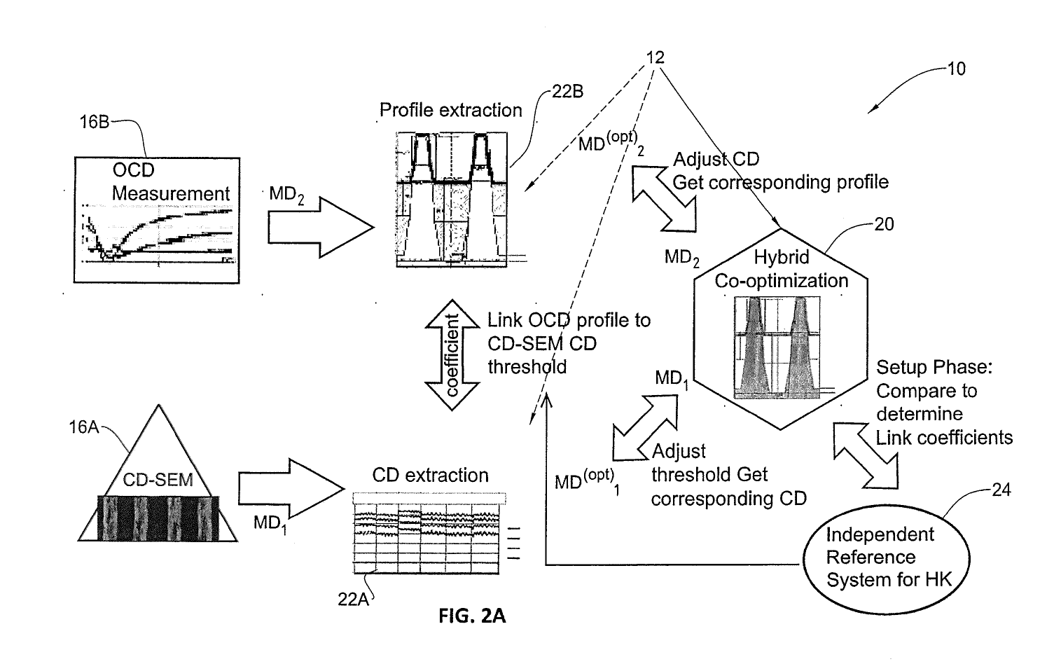

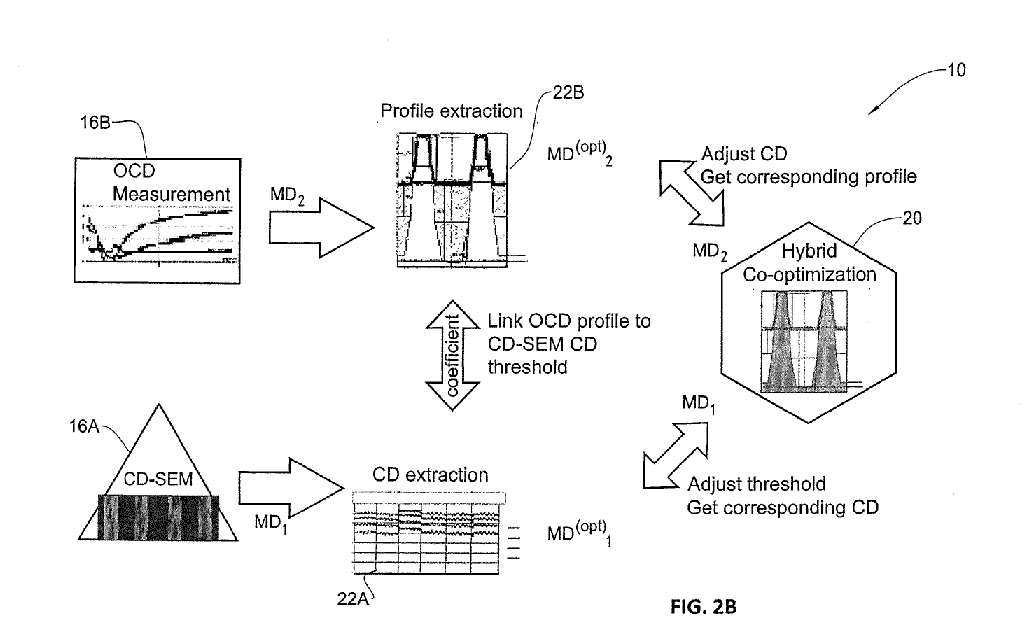

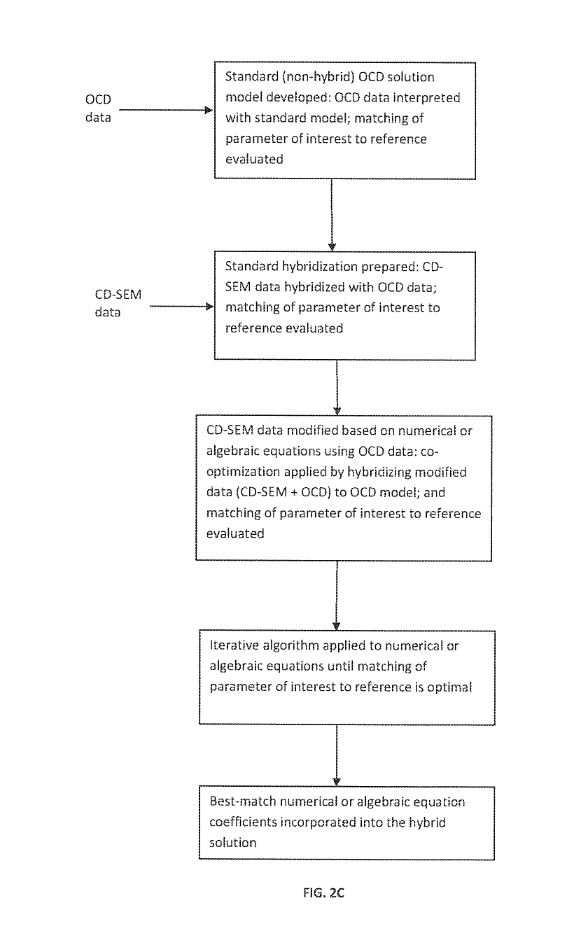

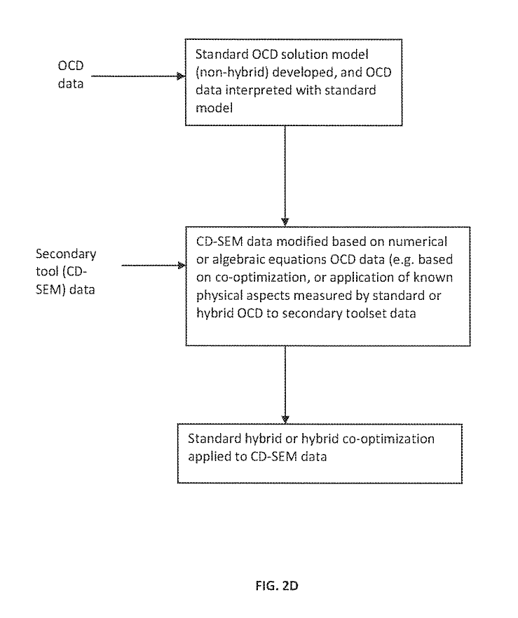

Reference is made to FIGS. 2A and 2B exemplifying the configuration and operation of the system 10 of the present invention for, respectively, a setup phase and a production phase of the measurement method of the invention. In the present example, the method includes measurement of a structure with CD-SEM, and measurement of the same structure with OCD.

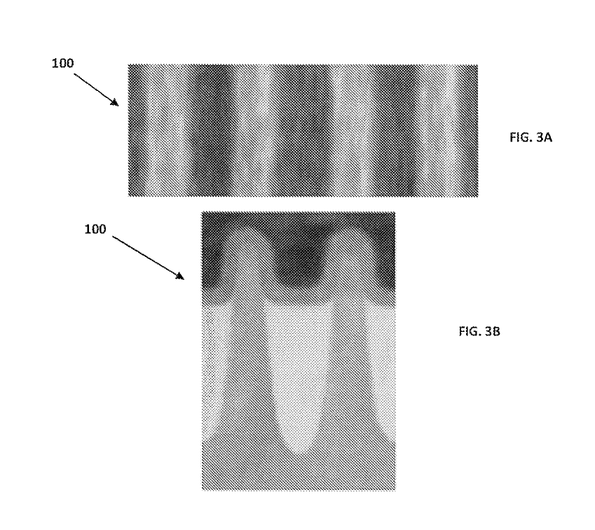

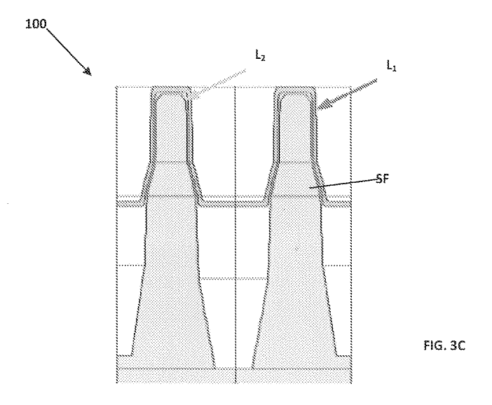

The specific example described herein concerns measurement on a complex 14 nm FinFET High-k/Interfacial layer structure. This structure is selected because it has stringent measurement requirements and complexity that not only challenged the non-hybrid approach but also the standard sequential Hybrid Metrology methodology. In this connection, reference is made to FIGS. 3A-3C.

FIGS. 3A and 3B show a fin structure with thin films deposited around, where FIG. 3A illustrates a typical top-down CD-SEM fragment of image and FIG. 3B illustrates a typical X-SEM lateral image to clarify some of the profile details, FIG. 3C illustrates the OCD model of the fin indicating some of the parameters of interest, showing some modeled profile details including 2-trapeze geometries for fin and trench, double-patterning effects on trench and fin alignment. The structure 100 includes a relatively thick High-k (HK<2 nm) layer L₁ and an interfacial layer (IL<1 nm) L₂ deposited on top of a Silicon Fin SF (formed using spacer-aligned double patterning and partial removal of trench dielectric). It should be noted that HK and IL are too thin to be clearly visible in top-down CD-SEM fragment and X-SEM lateral image, the thick “spacer-like” layer is sample preparation artifact and hence not present on actual structure.

Thus, the OCD model was parameterized to allow for a 2-trapeze profile extraction of the fin. Nine independent parameters were floated in order to fully characterize the fin structure, deposited layers and details of the dielectric-filled trench profile.

Turning back to FIGS. 2A and 2B, and also referring to FIG. 2C, the configuration and operation of the system 10 of the invention is more specifically exemplified, where the target parameter is HK thickness (layer L₁ in FIG. 3C) deposited on fin (SF in FIG. 3C).

As shown in the figures, CD-SEM and OCD measured data pieces MD₁ and MD₂ are provided from the CD-SEM and OCD tools 16A and 16B or storage devices as the case may be (generally, measured data provider utilities). These measured data pieces MD₁ and MD₂ are processed by respective processing utilities 22A and 22B which may be part of the hybrid server system 12 or of a separate processor connectable to the hybrid server 12.

In the example of FIG. 2A, exemplifying the setup phase of measurements, the processing utility 22A, and possibly also the hybrid co-optimization module 20, may also be connectable to a data provider unit 24 associated with an independent reference system for receiving therefrom reference data about thickness measurement of HK. The reference toolset/system may actively be used during the setup (“off-line”) phase to identify and set the CD-SEM threshold modulation coefficients. In the production phase (FIG. 2B), the reference is not needed, and the modulation is performed with the set coefficients (link) established during the setup phase.

As shown in the flow diagram of FIG. 2C, the OCD-related processor utility 22B may utilize a standard (non-hybrid) OCD solution model for interpreting the OCD measured data MD₂ and evaluating matching of parameter of interest to the reference, e.g. HK data from the reference system 24. The CD-SEM related processor utility 22A may operate to apply standard hybridization (hybridize secondary toolset data (CD-SEM) with primary toolset model (OCD)), and possibly evaluating matching of the parameter of interest to the reference, e.g. from an external reference system. Each CD-SEM image (data MD₁) may analyzed by the processor 22A with algorithms using two or more thresholds for the gray-scale histograms, and CD parameters are extracted; and each OCD spectrum (data MD₂) may be modeled by processor 22B and multiple profile parameters are extracted, as will be described below. The so-processed data MD₁ and MD₂ are input to the hybrid co-optimization module 20 of the hybrid server 12. The processed measured data MD₁ is indicative of CD parameters of the pattern, and processed measured data MD₂ is indicative of the pattern profile parameters. The hybrid co-optimization module 20 operates to modify the secondary toolset (CD-SEM) data (i.e. to adjust the thresholds for calculation of optimized CD parameters), based on numerical or algebraic equations using the primary toolset (OCD) data (i.e. adjust CD values to obtain corresponding optimized profile data). Thus, the co-optimization includes hybridization of the modified secondary toolset data (CD-SEM+OCD) to the primary toolset model (OCD)), and evaluating matching of the parameter of interest. The above is performed in iterations of the numerical or algebraic equations until matching of the parameter of interest to the reference is optimal (best matching), and the corresponding numerical or algebraic equation coefficients are incorporated into the hybrid solution.

The above technique can be used for recipe design in the production stage. In some examples, the CD-SEM data may be modified only once (based on standard OCD results). To this end, the OCD data may be measured and interpreted with standard recipe, and the CD-SEM data may be measured and interpreted with standard CD-SEM recipe. The CD-SEM data may be transferred to the OCD modeling engine (or common modeling engine). The CD-SEM data may be modified according to OCD standard results using numerical or algebraic equation coefficients determined during the setup stage. The modified CD-SEM data may be hybridized into the OCD model.

In some other examples, CD-SEM data may be continuously during hybrid fitting of OCD data. In these examples, in addition to the procedure described above, the following is carried: CD-SEM data is actively modified at every step of the hybrid fitting procedure using numerical or algebraic equation coefficients determined during the setup. At each fitting step, the CD-SEM data is applied being actively modified at either the previous step (based on the OCD profile parameters at that step), or the current fitting step.

The inventors have also developed a novel technique for using the OCD data to improve the CD-SEM data by noise removal therefrom. In this connection, reference is made to FIG. 2D showing a flow diagram of this technique. Similarly to the above-described techniques, standard OCD solution model (non-hybrid) is developed, and the measured OCD data is interpreted with the standard model. The CD-SEM data is modified based on numerical or algebraic equations using OCD data. The modification can be based on co-optimization setup flow, or on applying known physical aspects measured by standard or hybrid OCD to the CD-SEM data. Such aspects used as modifiers to secondary toolset data (CD-SEM data) can include (but not limited to) profile topography, interface or exposed surface area, relative or absolute volume of material layers or regions, etc. The so-modified CD-SEM data can undergo standard hybrid or hybrid co-optimization.

Turning back to FIGS. 3A-3C, in the experiments conducted by the inventor, DOE wafers were prepared with different deposition conditions to induce variation in HK and IL thickness (two key parameters to be measured for process control) as follows: 3 wafers with different HK modifications: POR, POR-2A, POR+2A; and 3 wafers with different IL modifications: POR, POR-2A, POR+12A. The two DOE sets (HK and IL modifications, respectively) were prepared at different times. While nominally each 3 wafers are identical except for the intended modifications, the two sets might inherently have small differences between each other, such as trench depth or fin height.

All wafers with full-wafer map sampling (all dies) were measured on CD-SEM and OCD. To account for spot size differences between CD-SEM (nm scale) and OCD (micron scale), multiple locations across the OCD target (50 μm box) were measured on CD-SEM, each location measuring about 10 lines and then an average was calculated. Full-wafer map reference measurements for High-K thickness were collected using the independent reference system (FIG. 2A).

For CD-SEM image analysis, the inventors utilized three edge detection measurement algorithm parameters A, B and C as potential candidates for co-optimization “knobs” (thresholds). Such adjustable parameters (A, B and C) are generic and could be found in most commercial CD-SEM edge detection algorithms to have a similar desired effect. For example, algorithms A and B affect aspects of the image noise reduction processes (as described above with reference to FIG. 2D), whereas algorithm parameter C modifies aspects of the histogram threshold cutoff (modulates the threshold of the grayscale image). In preparation to the CD-SEM data analysis, the algorithm parameters A, B and C were adjusted to modulate the image analysis. The resulting data is a partial 3-dimensional matrix of results (one dimension per algorithm parameter).

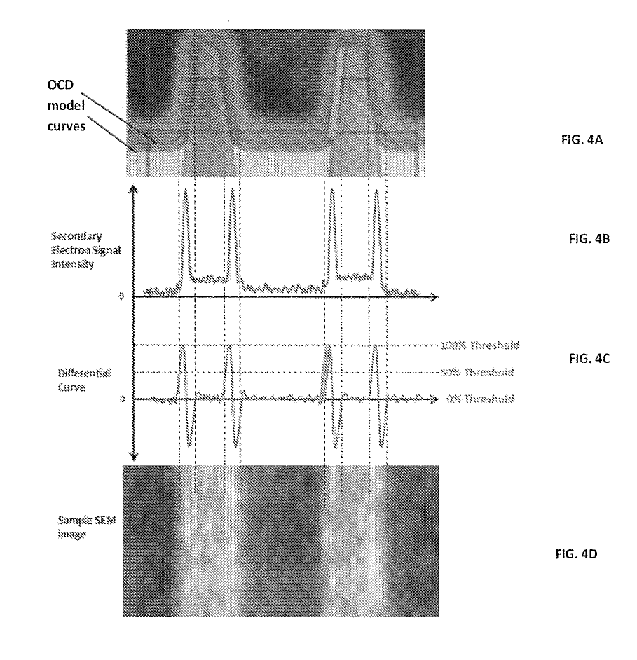

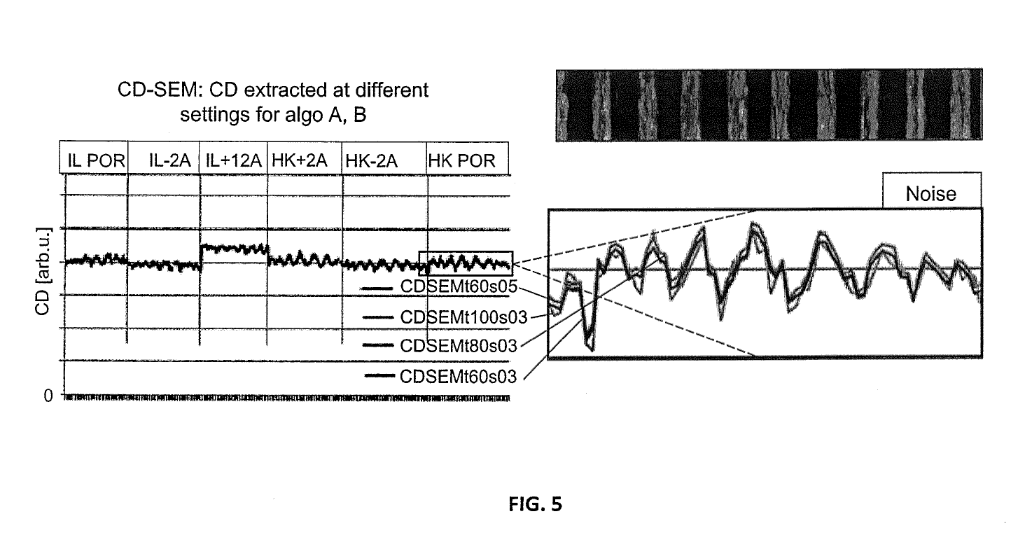

In this connection, reference is made to FIGS. 4A-4D and FIG. 5 showing schematics of the CD-SEM image analysis. FIG. 4A shows the sample TEM image (with HN and IL features) and corresponding OCD model curves. FIG. 4B shows secondary electron signal intensity. FIG. 4C shows the differential curve. FIG. 4D shows the sample SEM image. FIG. 5 shows the CD-SEM measurement of CD using different settings for algorithm parameters A and B for all 6 DOE wafers. All settings measure the same CD trend (great overlap, possibly slightly different noise levels between settings). The inventors have thus found that the effect of algorithm parameters A and B is rather subtle. The difference in CD is minimal (if any) both within-wafer and wafer-to-wafer, and is consistent with the image noise budget management (some settings appear to eliminate noise slightly better than others). However, no relevant, profile aware systematic differences in the overall level of CD extracted wafer-to-wafer or within-wafer can be inferred.

Algorithm parameter C selects the threshold cutoff for CD measurement on the histogram. Since the grayscale image is an aerial picture of a topographic feature on the wafer, a physical correspondence between gray level cutoffs and profile sections at different height of the fin was identified. The inventors have shown that the absolute value of the extracted CD varies with threshold.

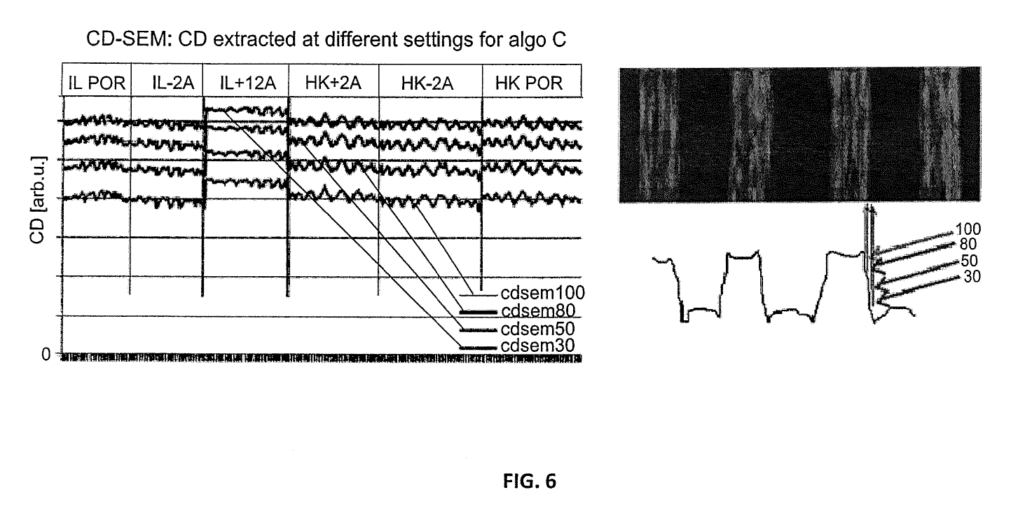

FIG. 6 illustrates CD extracted with the CD-SEM using different settings for algorithm parameter C. There is a quasi-constant offset depending on the threshold selected, i.e. the CD-SEM data extracted using algorithm parameter C shows a uniform variation top-to-bottom across wafers and dies. This is indicative of that either there is a correlation between profile height at which the CD is measured and gray scale threshold of the image analysis but the fin profile is very similar for all measured points (all dies), or that the algorithm parameter is rather insensitive to the profile, i.e. there is no real correlation between profile and the gray scale threshold analysis and actually only one independent parameter can be extracted to characterize the lateral dimension of the fin (and the histogram threshold cutoff is just that: an arbitrary fixed setting for CD reporting). If the CD extracted by CD-SEM depends on the sidewall profile then for a profile closer to vertical the extracted CD would be closer to constant (from top to bottom), whereas for a more tapered profile the CD would vary more top-to-bottom.

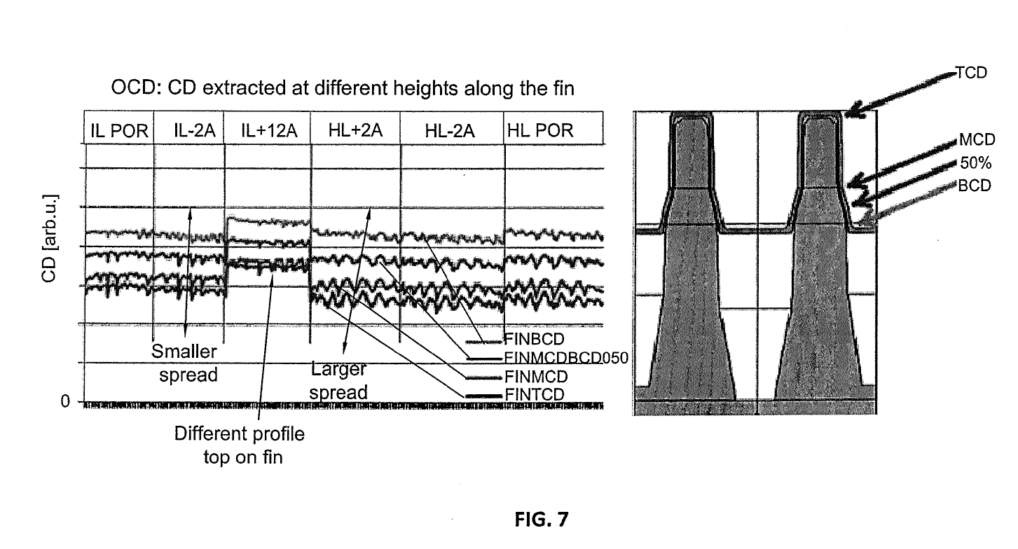

As for the OCD measurement, it extracts full profile of the fin. Reference is made to FIG. 7 which shows OCD measurements of CD along the fin (a few CD values are extracted along the fin for all dies). It can be seen that the profile is actually not constant between the wafers. For example, the IL DOE shows fins with larger SWA (larger deviation from vertical) than the HK DOE. More careful inspection also indicates that the SWA varies within wafer (the variations between extracted CDs are smaller towards the bottom of the fin). Finally, the IL+12A wafer has an almost vertical profile for the top part of the fin (TCD almost identical to MCD), whereas the other wafers show a less vertical profile.

In view of the above, it is evident that with the CD-SEM algorithm parameter C (the most promising for synergy with OCD) the CD-SEM is actually measuring only a single profile parameter. Threshold selection might be useful for selection of most stable gray level setting, but it does not seem to be directly connected with other profile details as reported by OCD. In order to still use this single-CD information for hybridization, one needs to go back to OCD and modulate the CD-SEM image analysis response in a manner consistent with the physics of secondary electrons collection.

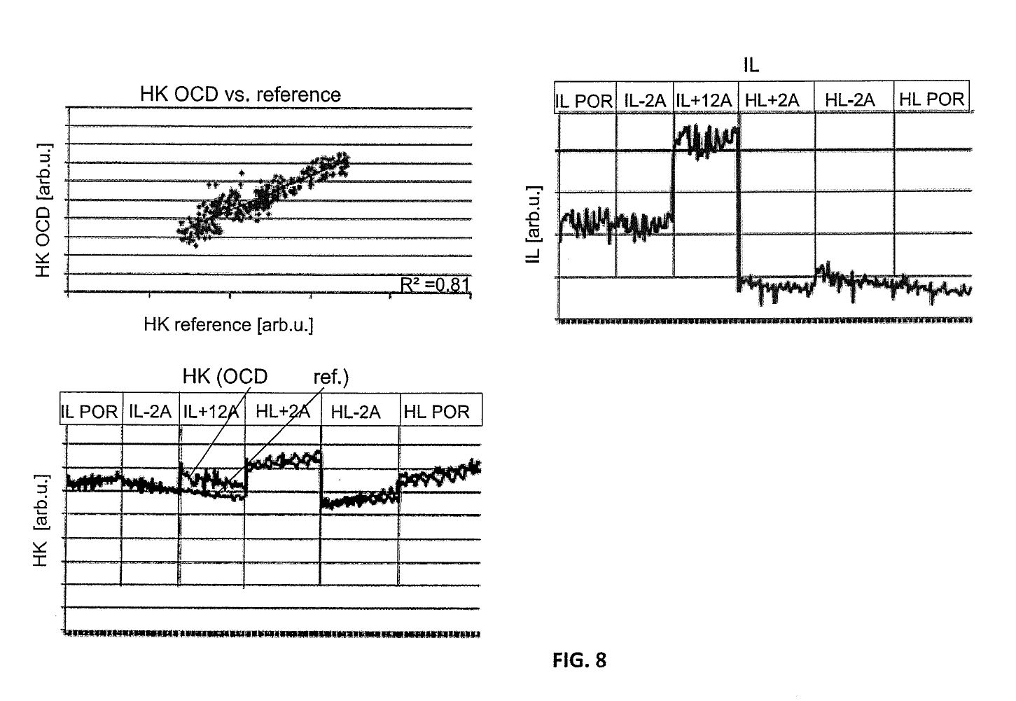

FIG. 8 shows “standard” OCD results for the parameters of interest, and comparison to reference (where available). The figure shows detailed information on extracted parameters for the 6 wafers. As can be seen, the HK measurement is relatively close to the reference (sub-Angstrom accuracy match) except for one of the IL wafers where there is more than 1 Angstrom offset, for an overall reasonable R2 of 0.81. The IL thickness is tracked but the DOE does not show a clear 2A offset between the first and second wafers. This result is encouraging, but it does not meet the specifications for process control.

In order to further improve the results, the CD measured data of CD-SEM may be applied as constraint to the OCD model. However, inducing such constraint using existing standard hybridization DMPs, for different CD-SEM image analysis, algorithm parameters settings quickly deteriorated the 0.81 R2 original matching to reference. Hence, the CD-SEM data might not be compatible in its current form with the OCD model.

Both CD-SEM and OCD data appear reasonable, but there is one more ingredient missing.

As also have been shown earlier, the threshold of the CD-SEM results can be effectively tuned using the sidewall angle (SWA) response from OCD. This was identified using a litho application with a focus-exposure matrix (FEM) which significantly altered the SWA of the printed photoresist features by comparing OCD and CD-SEM CD and identifying per-die algorithm threshold values for best match.

A fixed threshold algorithm provides CD values at different, yet unknown height along the fin. Standard hybridization existing DMPs does not provide a solution for this type of mismatch.

To make the two measurements compatible, the inventors actively adjusted the threshold of CD-SEM image analysis parameter per die using details of the OCD model in order to obtain a CD value measured at a consistent height along the profile. In order to do that, an overall SWA was identified for the fin structure of the OCD model. Then, fine tuning was performed with respect to the threshold in algorithm C consistent with this overall SWA (algorithm parameter C generated as a function of OCD SWA), the corresponding CD-SEM CD was extracted per die, and the result was hybridized into the OCD model. The improvement is qualified using matching of HK thickness to reference, and IL DOE tracking.

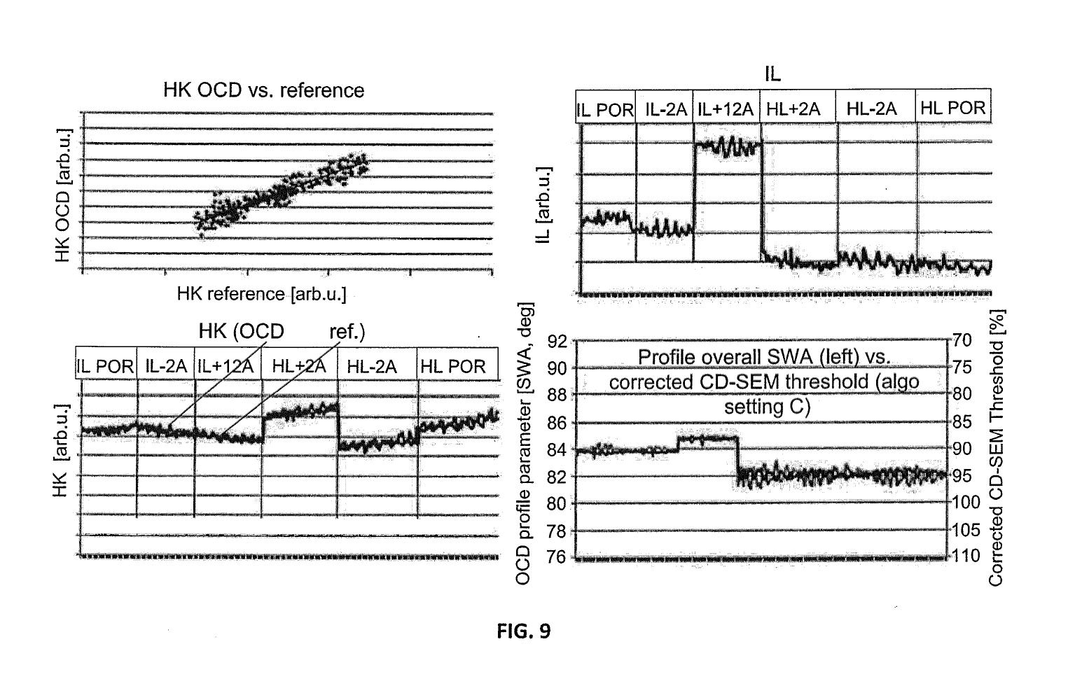

The result of this process is shown in FIG. 9, illustrating the results of threshold of CD-SEM algorithm C modulation using OCD profile details, which in turn are refined using corrected CD data from CD-SEM. The R² matching between OCD HK and reference HK improves to 0.91 along with about 40% improvement in accuracy performance (TMU). The IL DOE shows a 2A difference between wafers 1 and 2, as expected.

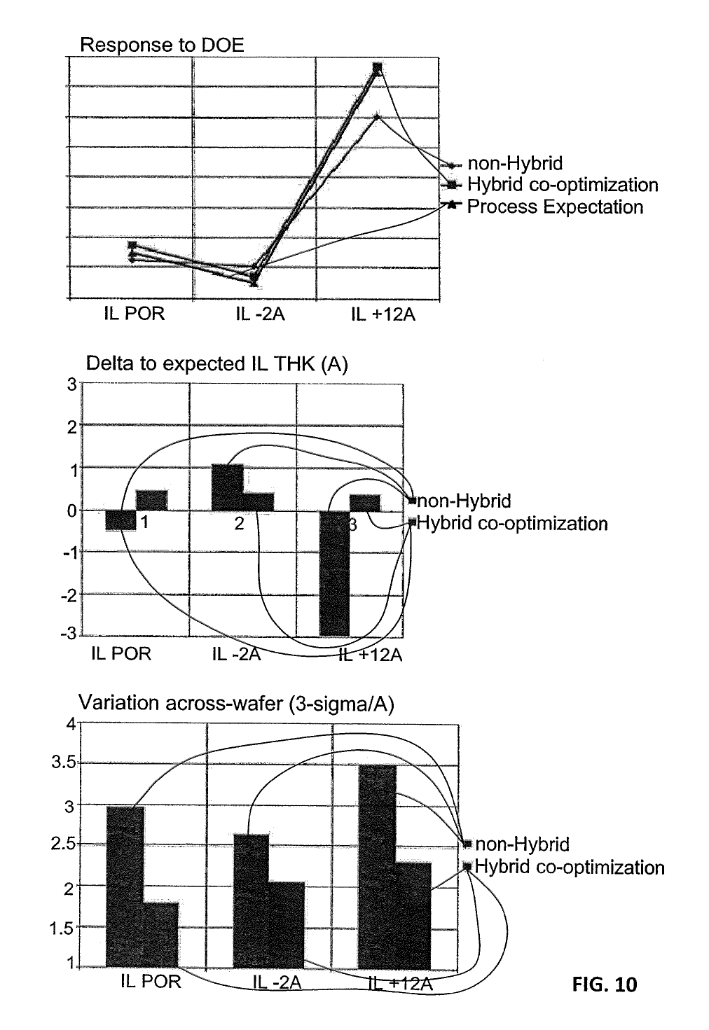

Reference is made to FIG. 10, showing the results of hybrid co-optimization technique of the invention applied to the measurements on IL DOE wafers. This figure shows the improved response to DOE conditions and less variation across-wafer for the co-optimization Hybrid Metrology vs. non-Hybrid Metrology. The improvement in measuring IL thickness is clearly demonstrated: better matching to expected DOE conditions as well as less noisy data across-wafer.

Thus, the technique of the present invention provides a significant improvement in measurements parameters of patterned structures, which technique is exemplified above for the co-optimization or concurrent/simultaneous hybridization, of CD-SEM and OCD measured data. As exemplified above, each CD-SEM image is analyzed with algorithms using two or more thresholds for the gray-scale histograms (FIG. 6). Each OCD spectrum is modeled and multiple parameters are extracted including sidewall angle of the profile and CD at different heights of the fin (FIG. 7). An independent reference system (24 in FIG. 2A) is used for thickness measurement of HK. The technique is aimed at improving the initial match between a reference measurement for HK and the values extracted with OCD (FIG. 8, R²=0.81). The method identifies a relevant profile parameter of the fin structure of the OCD model (e.g. SWA). A threshold value is selected, and is then fine-tuned consistent with this relevant parameter (FIG. 8), and a new corresponding CD-SEM CD is extracted per die, and then hybridized into the OCD model. The resulting OCD HK so hybridized is then compared again to the reference HK (FIG. 8, R²=0.89). The method uses one or more coefficients that link the CD-SEM threshold value to the OCD profile parameter value (for example, 0.1 degree variation can require in 1% change in threshold in order to keep the CD-SEM measurement at the same height along the fin). The method can interpolate between discrete threshold sets as measured in order to use CD at fractional threshold without the need of re-interpretation of CD-SEM images with specific thresholds for each die. The “best match” coefficients determined through improvement vs. reference are stored and can be subsequently used during hybridization of new wafers in the production phase of FIG. 2B (without the need of reference for HK thickness, which is now correctly extracted through co-optimization of CD-SEM and OCD).

The method extends the usability of Hybrid Metrology between CD-SEM and OCD to cases where the current Hybrid Metrology methods may fail to improve results to a sufficient level due to mismatch of measurement methods that was not previously accounted for. This is especially applicable to use-cases where the measure structures are challenging (such as 3D/FinFETs) and the measurement specifications are stringent (Angstrom level).

The method can be used in production via existing hybrid metrology path (with hybridization at tool level or at server level as described elsewhere) to enable higher performance of metrology than available today.

The inventors have shown that although the CD-SEM and OCD measure different aspects of a structure, the co-optimization hybridization technique of the invention provides for successively using these two measurement techniques together, because the CD-SEM threshold modulation (implemented using the OCD data) can be used as a function which reflects CD values at different heights of the structure. The height along the fin profile that corresponds to the CD measured renders the co-optimized hybridization successful. CD-SEM response is sensitive to profile detail. However, since it is capable of measuring a single independent parameter, a flat threshold, as used today, reflects CD values at different physical heights of the feature. This is especially true for the small CDs of the advanced features like FinFETs, where the “gray scale” edges of the lines represent an increasing percentage of the CD measured (“blur” is constant, CD decreases). Hence, CD-SEM may be used as “reference” for OCD. Many applications where “standard” hybrid was applied can further benefit from the refinements of co-optimization.

1. A computerized system for use in measuring at least one parameter of interest of a structure, the system comprising:
a server utility configured for data communication with at least first and second data provider utilities, for receiving therefrom measured data comprising first and second measured data pieces of different types indicative of parameters of the same structure, said server utility being configured and operable for concurrently processing said first and second measured data pieces for optimizing one or more first parameters values of the structure in one of the first and second measured data pieces by utilizing one or more second parameters values of the structure of the other of said first and second measured data pieces.

2. The system of claim 1, wherein the server utility comprises:
a first processing utility connected to the first data provider for receiving the first measured data piece and determining said one or more first parameters values;
a second processing utility connected to the second data provider for receiving the second measured data piece and determining said one or more second parameters values; and
a hybrid co-optimization utility connected to the first and second processing utilities, for receiving and processing said one or more first parameters values and said one or more second parameters values, and generating optimized model data for use by at least one of the first and second processing utilities for processing the respective measured data pieces.

3. The system of claim 1, wherein said server utility is further connectable to an additional data provider associated with a reference measurement system for providing reference data about at least one parameter of the same or similar structure.

4. The system of claim 1, wherein said first and second parameters include said at least one parameter of interest.

5. The system of claim 1, wherein the server utility is configured and operable for using at least one of said first and second parameters for determining said at least one parameter of interest.

6. The system of claim 1, wherein the at least one parameter of interest of the structure includes a parameter of a pattern in the structure.

7. The system of claim 1, wherein the at least one parameter of interest of the structure includes a thickness of a layer in the structure.

8. The system of claim 1, wherein the second measured data includes OCD measured data.

9. The system of claim 1, wherein the first measured data include either one or both of CD-SEM and X-ray measured data.

10. The system of claim 1, wherein the first and second measured data include respectively CD-SEM and OCD measured data.

11. The system of claim 1, being configured and operable for measuring one or more first parameters of the structure and comprising first data provider.

12. The system according to claim 1, wherein said structure is a patterned structure.

13. The system of claim 12, wherein said structure is a Field Effect Transistor.

14. The system of claim 10, wherein said server utility IS configured and operable for utilizing a threshold modulation of the CD-SEM measured data for determining critical dimension (CD) values along a profile of a pattern in the structure, as reference for analyzing the OCD measured data.

15. A measurement system for use in measuring at least one parameter of interest of a structure, the measurement system comprising:
at least first and second data provider utilities for providing measured data comprising first and second measured data pieces of different types indicative of parameters of the same structure; and
a server utility configured for data communication with said at least first and second data provider utilities, for receiving therefrom measured data comprising first and second measured data pieces of different types indicative of parameters of the same structure, said server utility being configured and operable for concurrently processing said first and second measured data pieces for optimizing one or more first parameter values of the structure in one of the first and second measured data pieces by utilizing one or more second parameters values of the structure of the other of said first and second measured data pieces.

16. The system of claim 15, wherein at least one of said at least first and second data providers is associated with a memory utility of a storage device.

17. The system of claim 15, wherein at least one of said at least first and second data providers is associated with a measurement tool.

18. The system of claim 15, wherein said server utility is further connectable to an additional data provider associated with a reference measurement system for providing reference data about at least one parameter of the same or similar structure.

19. The system of claim 15, wherein said structure is a patterned structure.

20. The system of claim 19, wherein said structure is a Field Effect transistor.

21. The system of claim 15, wherein the first and second measured data include respectively CD-SEM and OCD measured data.

22. The system of claim 15, wherein said server utility is configured and operable for utilizing a threshold modulation of the CD-SEM measured data for determining critical dimension (CD) values along a profile of a pattern in the structure, as reference for analyzing the OCD measured data.

23. A measurement tool for measuring at least one parameter of interest of a structure, the measurement tool comprising:
a measured data provider for providing data indicative of one or more measured parameters of a structure; and
a server utility configured for data communication with said measured data provider for receiving said data indicative of one or more measured parameters, and for data communication with at least one additional data provider utility for receiving therefrom at least one additional measured data piece of a different type indicative of one or more parameters of the same structure, said server utility being configured and operable for concurrently processing said measured data and said at least one additional measured piece for optimizing one or more parameters values of the structure in one of the measured data by utilizing one or more parameters values of the structure of the other of said measured data.

24. A method for use in measuring at least one parameter of interest of a structure, the method comprising:
receiving first measured data of a first type indicative of the structure, and processing said first measured data, and determining one or more first parameters values of the structure;
receiving second measured data of a second type indicative of the same structure, and processing said second measured data, and determining one or more second parameters values of the structure;
analyzing said first and second parameters values of the structure, and generating optimized model data for use in processing at least one of the first and second measured data.

25. The method of claim 24, wherein said structure is a patterned structure.

26. The method of claim 24, wherein said at least one parameter of interest includes at least one of the following: at least one parameter of a pattern in the structure; a thickness of a later in the structure.

27. The method of claim 24, wherein said structure is Field Effect Transistor.

28. The method of claim 24, wherein the first and second measured data include respectively CD-SEM and OCD measured data.

29. The method of claim 28, wherein said analyzing of the first and second parameters values of the structure comprises utilizing Image based threshold modification of CD-SEM measured data for optimizing modeling of the OCD measurements.
